(19) United States
(12) Patent Application Publication
(10) Pub. No.: US 2017/0025386 A1
(43) Pub. Date: Jan. 26, 2017

(54) SEMICONDUCTOR DEVICE

(71) Applicant: SHINKO ELECTRIC INDUSTRIES CO., LTD., Nagano (JP)

(72) Inventor: Shota MIKI, Nagano (JP)

(21) Appl. No.: 15/190,313

(22) Filed: Jun. 23, 2016

(30) Foreign Application Priority Data
Jul. 24, 2015 (JP) 2015-146891

(51) Int. Cl. H01L 25/065; H01L 25/00

(52) U.S. Cl. CPC H01L 25/0657; H01L 25/50; H01L 2225/06513; H01L 2225/06544; H01L 2225/06555; H01L 2225/06582

(57) ABSTRACT

A semiconductor device includes a first semiconductor chip and a second semiconductor chip stacked on the first semiconductor chip in a stacking direction. The first semiconductor chip includes a through electrode and a pad on an end face of the through electrode, facing toward the second semiconductor chip. The second semiconductor chip includes a connection terminal at a surface thereof facing toward the first semiconductor chip. The end face of the through electrode and a surface of the connection terminal, facing toward the first semiconductor chip, do not overlap each other when viewed in the stacking direction. The pad and the connection terminal are electrically connected by a bonding part.

### CROSS-REFERENCE TO RELATED APPLICATION

This application is based upon and claims the benefit of priority of the prior Japanese Patent Application No. 2015-146891, filed on Jul. 24, 2015, the entire contents of which are incorporated herein by reference.

### FIELD

A certain aspect of the embodiments discussed herein is related to semiconductor devices and methods of manufacturing the same.

### BACKGROUND

In recent years, there has been a demand for smaller (thinner) semiconductor chip packages of a higher pin count and higher density. In order to meet such a demand, the system in package (SiP), which mounts multiple semiconductor chips on a single wiring board, has been put to practical use.

In particular, an SiP using a three-dimensional packaging technology that three-dimensionally stacks multiple semiconductor chips, or a so-called stacked chip package, has the advantage of making it possible to reduce wiring length, in addition to the advantage of making it possible to achieve high integration. As a result, it is possible to increase circuit operation speed and reduce wiring stray capacitance. Therefore, stacked chip packages are widely used.

For example, as an SiP using a three-dimensional packaging technology, a structure is proposed where a first semiconductor chip in which through electrodes are formed is stacked on a wiring board, and a second semiconductor chip is stacked on the first semiconductor chip. (See, for example, Japanese Laid-open Patent Publication No. 2013-55313.) According to this structure, the wiring board and the second semiconductor chip are electrically connected through the through electrodes of the first semiconductor chip.

### SUMMARY

According to an aspect of the invention, a semiconductor device includes a first semiconductor chip and a second semiconductor chip stacked on the first semiconductor chip in a stacking direction. The first semiconductor chip includes a through electrode and a pad on an end face of the through electrode, facing toward the second semiconductor chip. The second semiconductor chip includes a connection terminal at a surface thereof facing toward the first semiconductor chip. The end face of the through electrode and a surface of the connection terminal, facing toward the first semiconductor chip, do not overlap each other when viewed in the stacking direction. The pad and the connection terminal are electrically connected by a bonding part.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a cross-sectional view of a semiconductor device according to a first embodiment;

FIG. 2 is a see-through plan view of the semiconductor device, depicting connections of semiconductor chips, according to the first embodiment;

FIGS. 3A and 3B are enlarged views of part of the semiconductor device, depicting a structure of the connections of the semiconductor chips;

FIG. 4 is an enlarged cross-sectional view of part of a semiconductor device, depicting a structure of connections of semiconductor chips, according to a comparative example;

FIGS. 5A through 5E are diagrams depicting a process of manufacturing a semiconductor device according to the first embodiment;

FIG. 6 is a cross-sectional view of a semiconductor device according to a second embodiment;

FIG. 7 is an enlarged view of part of FIG. 6 indicated by B; and

FIGS. 8A and 8B are enlarged views of part of a semiconductor device, depicting a structure of connections of semiconductor chips, according to a variation of the first embodiment.

### DESCRIPTION OF EMBODIMENTS

As described above, there is an SiP where a first semiconductor chip is stacked on a wiring board, and a second semiconductor chip is mounted on the first semiconductor chip to be electrically connected to the wiring board via through electrodes formed in the first semiconductor chip. According to such an SIP, however, pads are formed on the through electrodes exposed at the upper surface of the first semiconductor chip, and connection terminals of the second semiconductor chip are disposed immediately above the pads to be soldered to the pads. The through electrodes are thus positioned immediately below the connection terminals of the second semiconductor chip. Therefore, a problem such as generation of a crack in a through electrode may be caused when the second semiconductor chip is mounted or when the ambient temperature repeatedly changes after the mounting of the second semiconductor chip. In particular, as the through electrode diameter becomes smaller, such a problem becomes more likely to occur to reduce the reliability of the connection of the first semiconductor chip and the second semiconductor chip.

According to an aspect of the present invention, it is possible to provide a semiconductor device that improves the reliability of the connection of a first semiconductor chip including through electrodes and a second semiconductor chip mounted on the first semiconductor chip.

Preferred embodiments of the present invention will be explained with reference to accompanying drawings. In the drawings, the same elements or configurations are referred to using the same reference numeral, and a repetitive description thereof may be omitted.

### [a] First Embodiment

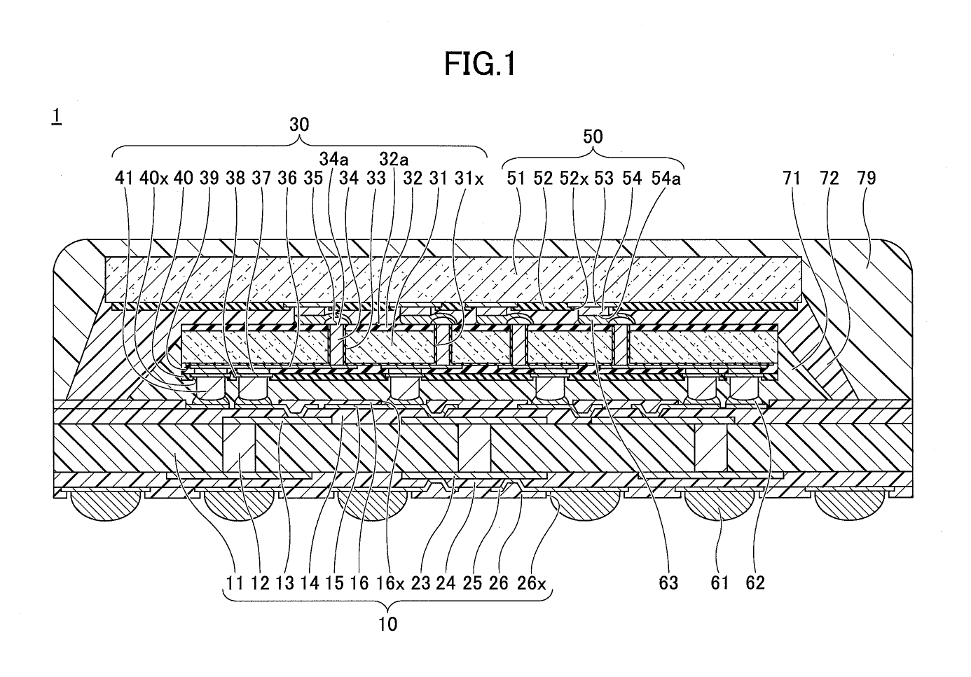

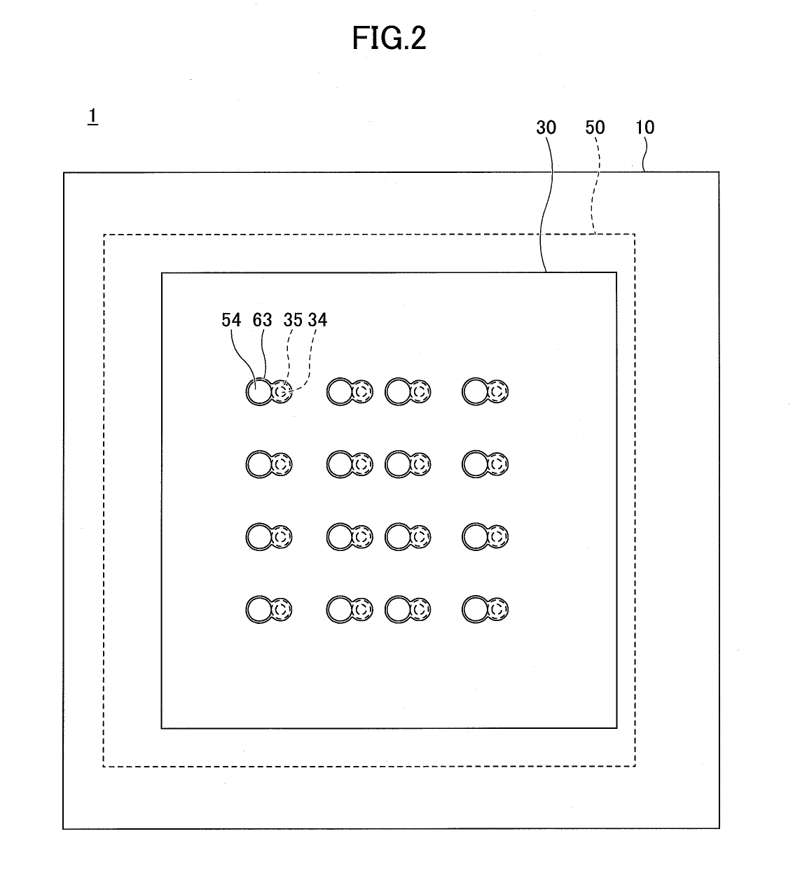

First, a structure of a semiconductor device according to a first embodiment is described. FIG. 1 is a cross-sectional view of a semiconductor device according to the first embodiment. FIG. 2 is a see-through plan view of the semiconductor device, depicting connections of semiconductor chips.

Referring to FIGS. 1 and 2, a semiconductor device 1 includes a wiring board 10, a semiconductor chip 30, and a semiconductor chip 50. The semiconductor chip 30 and the semiconductor chip 50 are successively stacked on the wiring board 10.

According to this embodiment, for convenience of description, the semiconductor chip 50 side of the semiconductor device 1 will be referred to as “upper side” or “first side,” and the wiring board 10 side of the semiconductor device 1 will be referred to as “lower side” or “second side.” Furthermore, with respect to each part or element of the semiconductor device 1, a surface on the semiconductor chip 50 side will be referred to as “upper surface” or “first surface,” and a surface on the wiring board 10 side will be referred to as “lower surface” or “second surface.” The semiconductor device 1, however, may be used in an inverted position or oriented at any angle. Furthermore, a plan view refers to a view of an object taken in a direction normal to the first surface of the wiring board 10, and a planar shape refers to the shape of an object viewed in a direction normal to the first surface of the wiring board 10. The direction normal to the first surface of the wiring board 10 may be considered as a direction in which the semiconductor chip 50 is stacked on the semiconductor chip 30.

The wiring board 10 includes a core layer 11, a wiring layer 13, an insulating layer 14, a wiring layer 15, a solder resist layer 16, a wiring layer 23, an insulating layer 24, a wiring layer 25, and a solder resist layer 26. The wiring layer 13, the insulating layer 14, the wiring layer 15, and the solder resist layer 16 are successively stacked on the first surface of the core layer 11. The wiring layer 23, the insulating layer 24, the wiring layer 25, and the solder resist layer 26 are successively stacked on the second surface of the core layer 11.

As the core layer 11, for example, a so-called glass epoxy substrate, which is glass cloth impregnated with an epoxy resin, may be used. Vias 12 are formed in the core layer 11 to penetrate through the core layer 11 in a direction of its thickness.

The wiring layer 13 is formed on the first surface of the core layer 11. The wiring layer 23 is formed on the second surface of the core layer 11. The wiring layers 13 and 23 are electrically connected by the vias 12. Suitable materials for the wiring layers 13 and 23 and the vias 12 include, for example, copper (Cu). The thickness of the wiring layers 13 and 23 may be, for example, approximately 10 μm to approximately 30 μm. The vias 12 and the wiring layers 13 and 23 may be monolithically formed.

The insulating layer 14 is formed on the first surface of the core layer 11 to cover the wiring layer 13. Suitable materials for the insulating layer 14 include, for example, an insulating resin whose principal component is epoxy resin. The insulating layer 14 may contain a filler, such as silica (SiO₂). The thickness of the insulating layer 14 may be, for example, approximately 15 μm to approximately 35 μm.

The wiring layer 15 is formed on the upper surfaces of the wiring layer 13 and the insulating layer 14. The wiring layer 15 includes vias, each formed on an inner wall surface of one of via holes penetrating through the insulating layer 14 to expose the upper surface of the wiring layer 13, and wiring patterns formed on the upper surface of the insulating layer 14. The wiring layer 15 may use the same material as the wiring layer 13, for example.

The solder resist layer 16 is formed on the upper surface of the insulating layer 14 to cover the wiring layer 15. The solder resist layer 16 has openings 16x. Part of the wiring layer 15 is exposed in the openings 16x to form pads for connection to the semiconductor chip 30. The solder resist layer 16 may be formed of, for example, a photosensitive resin, such as a photosensitive epoxy resin or a photosensitive acrylic resin. The thickness of the solder resist layer 16 may be, for example, approximately 15 μm to approximately 35 μm.

The insulating layer 24 is formed on the second surface of the core layer 11 to cover the wiring layer 23. The material and the thickness of the insulating layer 24 may be the same as those of the insulating layer 14, for example. The insulating layer 24 may contain a filler, such as silica.

The wiring layer 25 is formed on the lower surfaces of the wiring layer 23 and the insulating layer 24. The wiring layer 25 includes vias, each formed on an inner wall surface of one of via holes penetrating through the insulating layer 24 to expose the lower surface of the wiring layer 23, and wiring patterns formed on the lower surface of the insulating layer 24. The wiring layer 25 may use the same material as the wiring layer 23, for example.

The solder resist layer 26 is formed on the lower surface of the insulating layer 24 to cover the wiring layer 25. The solder resist layer 26 has openings 26x. Part of the wiring layer 25 is exposed in the openings 26x. The wiring layer 25 exposed in the openings 26x may be used as pads for electrical connection to a mounting board (not depicted) such as a motherboard. The material, etc., of the solder resist layer 26 may be the same as those of the solder resist layer 16, for example. Solder bumps 61 may be formed on the lower surface of the wiring layer 25 exposed in the openings 26x.

The semiconductor chip 30 (a first semiconductor chip) is mounted face down on the first surface of the wiring board 10 by flip chip bonding, so that the second or circuit-formation surface of the semiconductor chip 30, on which a circuit is formed, faces toward the first surface of the wiring board 10. The semiconductor chip 30 includes a semiconductor substrate 31, an insulating layer 32, an insulating film 33, through electrodes 34, pads 35, a wiring layer 36, vias 37, pads 38, an insulating layer 39, a protection film 40, and connection terminals 41.

Suitable materials for the semiconductor substrate 31 include, for example, silicon (Si). The thickness of the semiconductor substrate 31 may be, for example, approximately 30 μm to approximately 200 μm. The semiconductor substrate 31 is, for example, one of individual pieces into which a thinned silicon wafer is divided.

The insulating layer 32 covers the first surface of the semiconductor substrate 31 (on the opposite side of the semiconductor substrate 31 from the circuit-formation surface). Suitable materials for the insulating layer 32 include, for example, an insulating resin, such as epoxy resin or polyimide resin. The thickness of the insulating layer 32 may be, for example, approximately 10 μm to approximately 50 μm.

The insulating layer 33 continuously covers the second surface of the semiconductor substrate 31 and inner wall surfaces of through holes 31x penetrating through the semiconductor substrate 31 and the insulating layer 32. As the insulating film 33, for example, a silicon oxide film or a silicon nitride film may be used. The thickness of the insulating film 33 may be, for example, approximately 0.5 μm to approximately 1.0 μm.

The through electrodes 34 fill in the through holes 31x covered with the insulating film 33. The planar shape of the through electrodes 34 may be, for example, a circle, and the diameter of the through electrodes 34 may be, for example, approximately 10 μm to approximately 20 μm. The pitch of the through electrodes 34 may be, for example, approximately 40 μm to approximately 100 μm. The through electrodes 34 may be formed of, for example, copper.

For example, upper end faces 34a (first end faces) of the through electrodes 34 are substantially flush with an upper surface 32a of the insulating layer 32, which forms part of the first surface of the semiconductor chip 30, on the first surface side of the semiconductor substrate 31. Pads 35 are formed on the upper end faces 34a of the through electrodes 34. The pads 35 are described in detail below.

For example, the lower end faces (second end faces) of the through electrodes 34 are substantially flush with the lower surface of the insulating film 33 on the second surface side of the semiconductor substrate 31. The lower end faces of the through electrodes 34 are electrically connected to the wiring layer 36.

The wiring layer 36 is formed on the lower surface of the insulating film 33 that covers the second surface of the semiconductor substrate 31. The wiring layer 36 is electrically connected to the pads 38 through the vias 37. That is, the wiring layer 36 and the vias 37 electrically connect the through electrodes 34 and the pads 38. Suitable materials for the wiring layer 36 and the vias 37 include, for example, copper. Suitable materials for the pads 38 include, for example, aluminum (Al).

The insulating layer 39 covers the wiring layer 36 and the vias 37. Suitable materials for the insulating layer 39 include, for example, low dielectric materials having a small dielectric constant (so-called low-k materials). Examples of low dielectric materials include SiOC, SiOF, and organic polymer materials. The dielectric constant of the insulating layer 39 may be, for example, approximately 3.0 to approximately 3.5. The thickness of the insulating layer 39 may be, for example, approximately 0.5 μm to approximately 2.0 μm.

The protection film 40 is formed on the lower surface of the insulating layer 39 to cover the pads 38. The protection film 40 has openings 40x. The pads 38 are exposed in the openings 40x. The protection film 40, which is a film for protecting a semiconductor integrated circuit formed on the semiconductor substrate 31, may also be referred to as “passivation film.” As the protection film 40, for example, a SiN, film or a PSG film may be used. A laminate formed by stacking a layer of polyimide or the like on a layer of a SiN film or a PSG film may also be used as the protection film 40.

The connection terminals 41 are formed on the lower surfaces of the pads 38 exposed in the openings 40x. The connection terminals 41 are substantially columnar connection bumps extending downward from the lower surfaces of the pads 38. The connection terminals 41 are electrically connected to the through electrodes 34 and the semiconductor integrated circuit formed on the semiconductor substrate 31. The height of the connection terminals 41 may be, for example, approximately 20 μm to approximately 40 μm. The diameter of the connection terminals 41 may be, for example, approximately 10 μm to approximately 40 μm. Suitable materials for the connection terminals 41 include, for example, copper.

The connection terminals 41 are electrically connected, through bonding parts 62 formed of solder or the like, to the wiring layer 15 exposed in the openings 16x of the wiring board 10.

The semiconductor chip 50 (a second semiconductor chip) includes a semiconductor substrate 51, a protection film 52, pads 53, and connection terminals 54. The semiconductor chip 50 is stacked on the first semiconductor chip 30 with the second surface of the semiconductor chip 50, at which the connection terminals 54 are formed, facing the first surface of the semiconductor chip 30, at which the pads 35 are formed. In other words, the semiconductor chip 50 is mounted face down on the first surface of the semiconductor chip 30 (opposite to the circuit-formation surface) by flip chip bonding.

Suitable materials for the semiconductor substrate 51 include, for example, silicon. The thickness of the semiconductor substrate 51 may be, for example, approximately 30 μm to approximately 200 μm. The semiconductor substrate 51 is, for example, one of individual pieces into which a thinned silicon wafer is divided.

The protection film 52 covers the second surface of the semiconductor substrate 51. The protection film 52 is a film for protecting a semiconductor integrated circuit formed on the semiconductor substrate 51. The material, etc., of the protection film 52 may be the same as those of the protection film 40, for example.

The pads 53 are formed on the second surface of the semiconductor substrate 51 and electrically connected to the semiconductor integrated circuit of the semiconductor substrate 51. The lower surfaces of the pads 53 are exposed in openings 52x formed in the protection film 52. Suitable materials for the pads 53 include, for example, aluminum.

The connection terminals 54 are formed on the lower surfaces of the pads 53 exposed in the openings 52x. As the connection terminals 54, for example, a Ni/Au/Sn layer (a laminated metal layer of a nickel [Ni] layer, a gold [Au] layer, and a tin [Sn] layer that are stacked in this order) or a Ni/Pd/Au/Sn layer (a laminated metal layer of a Ni layer, a palladium [Pd] layer, a Au layer, and a Sn layer that are stacked in this order), formed by an Al zincate process or electroless plating, may be used.

Alternatively, as the connection terminals 54, for example, a Ni/Au layer (a laminated metal layer of a Ni layer and a Au layer that are stacked in this order) or a Ni/Pd/Au layer (a laminated metal layer of a Ni layer, a Pd layer, and a Au layer that are stacked in this order), formed by an Al zincate process or electroless plating, may be used.

As yet another alternative, for example, columnar connection bumps on which a solder layer is formed may be used as the connection terminals 54. In this case, suitable materials for the connection bumps include, for example, copper, and suitable materials for the solder layer include, for example, lead-free solder (such as tin-silver [Sn—Ag] solder).

The connection terminals 54 are electrically connected to the pads 35 of the semiconductor chip 30 through bonding parts 63 formed of solder or the like.

The space between the wiring board 10 and the semiconductor chip 30 is filled with an underfill resin 71 that covers the connection terminals 41 and the bonding parts 62. The space between the semiconductor chip 30 and the semiconductor chip 50 is filled with an underfill resin 72 that covers the connection terminals 54 and the bonding parts 63. The underfill resin 72 extends onto the periphery of the underfill resin 71 between the wiring board 10 and the semiconductor chip 50. Furthermore, an encapsulation resin 79, which encapsulates the semiconductor chips 30 and 50 and the underfill resins 71 and 72, is provided on the wiring board 10. Suitable materials for the underfill resins 71 and 72 and the encapsulation resin 79 include, for example, epoxy resin.

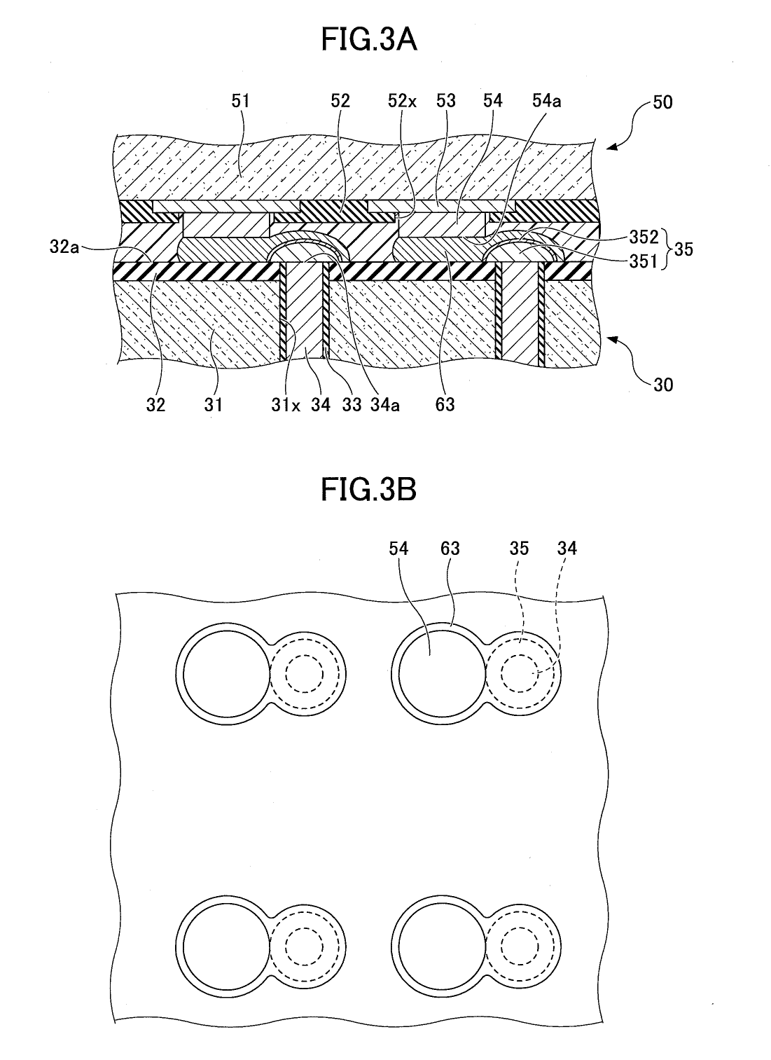

FIGS. 3A and 3B are enlarged views of part of the semiconductor device 1 of FIG. 1, depicting a structure of connections of semiconductor chips. FIG. 3A is a cross-sectional view, and FIG. 33 is a see-through plan view. In the following description, the pads 35 may be collectively referred to as “pad 35” and the through electrodes 34 may be collectively referred to as “through electrode 34.” Furthermore, the connection terminals 54 may be collectively referred to as “connection terminal 54.” As described above, the pad 35 is formed on the upper end face 34a of the through electrode 34 in the semiconductor chip 30. The planar shape of the pad 35 is, for example, a circle. The peripheral portion of the pad 35 extends beyond the perimeter of the upper end face 34a of the through electrode 34 (onto the upper surface 32a of the insulating layer 32). The diameter of the through electrode 34 is, for example, approximately 5 μm to approximately 20 μm. The peripheral portion of the pad 35 extends, for example, a few micrometers beyond the perimeter of the upper end face 34a of the through electrode 34 onto the upper surface 32a of the insulating layer 32. The peripheral portion of the pad 35 is indicated as an annular portion around the upper end face 34a of the through electrode 34 in FIG. 3B.

The pad 35 includes an inner plating layer 351, which contacts the upper end face 34a of the through electrode 34 to extend onto the upper surface 32a of the insulating layer 32, and an outer plating layer 352, which covers the entire top (exterior) surface of the inner plating layer 351. The pad 35 has a convex dome shape, whose height decreases in a direction from the center to the periphery. The height of the center (where the pad 35 is highest) may be, for example, approximately a few micrometers.

The pad 35 having a convex shape may be formed by electroless plating. According to electroless plating, plating is performed without forming a resist layer on the insulating layer 32. Accordingly, plating grows isotropically from the upper end face 34a of the through electrode 34 to form the convex pad 35. In electroless plating, for example, a Ni layer may be used as the inner plating layer 351. Alternatively, a Ni/Pd layer (a laminated metal layer of a Ni layer and a Pd layer that are stacked in this order) may be used as the inner plating layer 351. As the outer plating layer 352, for example, a Au layer may be used.

The semiconductor chip 30 and the semiconductor chip 50 are disposed without the upper end face 34a of the through electrode 34, facing toward the semiconductor chip 50, and a second surface 54a of the connection terminal 54, facing toward the semiconductor chip 30, overlapping each other in a plan view. The pad 35 of the semiconductor chip 30 is electrically connected to the connection terminal 54 of the semiconductor chip 50 through the corresponding bonding part 63 formed of solder.

As long as a surface of the through electrode 34 facing toward the semiconductor chip 50, namely, the upper end face 34a, and the second surface 54a of the connection terminal 54, facing toward the semiconductor chip 30, do not overlap each other in a plan view, the through electrode 35 and the connection terminal 54 may overlap each other in a plan view.

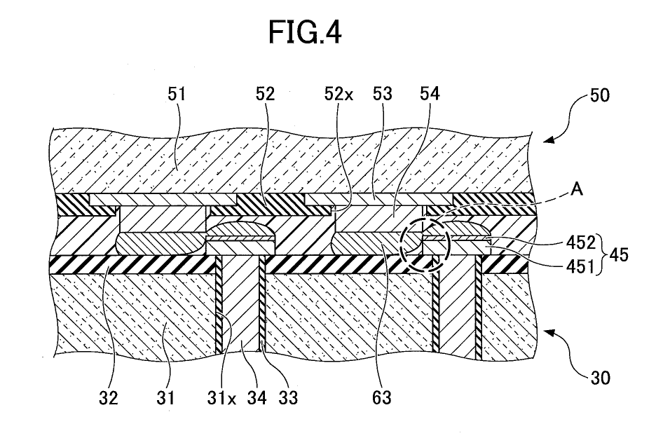

FIG. 4 is an enlarged cross-sectional view of part of a semiconductor device according to a comparative example, depicting a structure of connections of semiconductor chips. The connections according to the comparative example have the same structure as the structure depicted in FIG. 3A except that the pads 35 are replaced with pads 45 (hereinafter collectively referred to as “pad 45”).

The pad 45 is formed by electroplating. Unlike the pad 35, which has a convex shape, the pad 45 has a disk shape. According to the pad 45, an upper plating layer 452 is formed to cover the upper surface of a lower plating layer 451, while the upper plating layer 452 is not formed on the side surface of the lower plating layer 451. The material of the lower plating layer 451 is the same as the material of the inner plating layer 351, and the material of the upper plating layer 451 is the same as the material of the outer plating layer 352.

To form the pad 45 by electroplating, first, a seed layer of copper or the like is formed on the insulating layer 32 by electroless plating. Next, a resist layer having an opening corresponding to the pad 45 is formed on the seed layer. Then, electroplating is performed, using the seed layer as a power feed layer, to form the lower plating layer 451 in the opening of the resist layer and stack the upper plating layer 452 on the upper surface of the lower plating layer 451.

Next, after removal of the resist layer, an unnecessary portion of the seed layer is removed by etching, using the lower plating layer 451 and the upper plating layer 452 as a mask. As a result, the pad 45, having the lower plating layer 451 and the upper plating layer 452 stacked on the seed layer, is formed. In FIG. 4, a depiction of the seed layer is omitted.

As will be appreciated from the above description, when the upper plating layer 452 is formed, the upper plating layer 452 is not formed on the side surface of the lower plating layer 451 because the side surface of the lower plating layer 451 is covered with the resist layer. Furthermore, because plating deposits evenly in the opening of the resist layer, the lower plating layer 451 and the upper plating layer 452 do not have a convex shape but have a disk shape.

Thus, the pad 45 formed by electroplating has a disk shape, and the upper plating layer 452 is not formed on the side surface of the lower plating layer 451. Therefore, as depicted in a circle indicated by A in FIG. 4, the bonding part 63 is formed on the upper plating layer 452 formed of, for example, a Au layer having good wettability with solder, while the bonding part 63 is not formed on the side surface of the lower plating layer 451 formed of, for example, a Ni layer having poor wettability with solder. As a result, if the through electrode 34 and the connection terminal 54 are positioned offset from each other, the amount of the bonding part 63 at the connection of the pad 35 on the through electrode 34 and the connection terminal 54 becomes extremely small, thus preventing the through electrode 34 and the connection terminal 54 from being connected with high reliability.

In contrast, according to this embodiment, as described with reference to FIGS. 3A and 3B, the convex pad 35 is formed on the through electrode 34, and the topmost surface of the pad 35 is defined by the outer plating layer 352 formed of, for example, a Au layer having good wettability with solder, of which the bonding part 63 is formed. As a result, even when the through electrode 34 and the connection terminal 54 are positioned offset from each other, wet solder spreads over the entire top surface of the outer plating layer 352, so that the amount of the boding part 63 at the connection of the pad 35 and the connection terminal 54 becomes sufficiently large. Therefore, the through electrode 34 and the connection terminal 54 are connected with high reliability through the pad 35 and the boding part 63.

It is desired that the amount of the bonding part 63 at the connection of the pad 35 and the connection terminal 54 is sufficiently large, and if that amount is sufficiently large, it is not necessary for solder to be wet and spread to completely cover the entire top surface of the outer plating layer 352 (the same applies hereinafter).

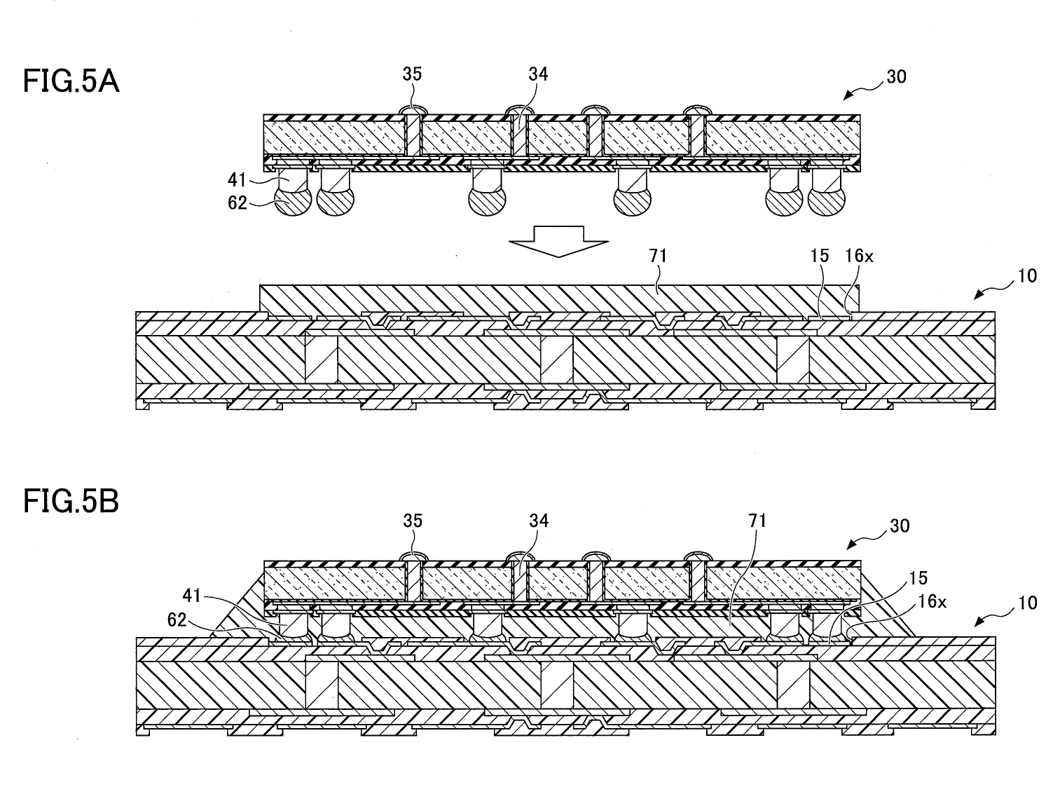

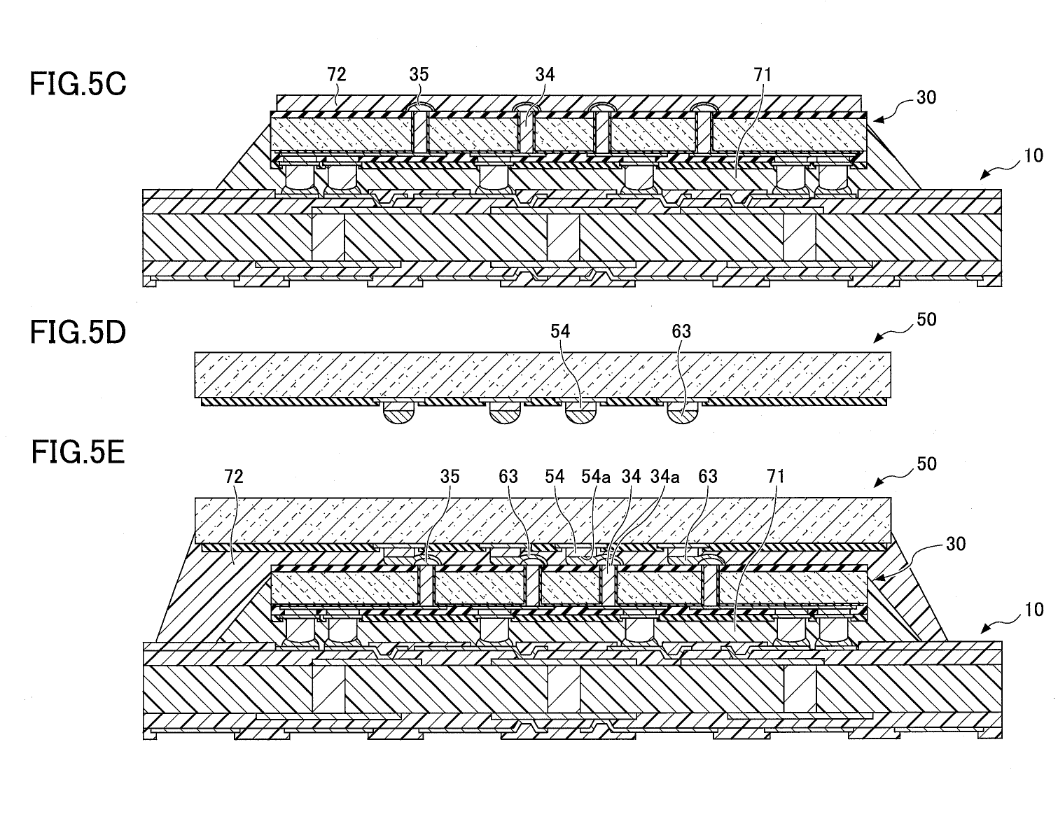

Next, a method of manufacturing a semiconductor device according to the first embodiment is described. FIGS. 5A through 5E are diagrams depicting a process of manufacturing a semiconductor device according to the first embodiment.

First, in the process depicted in FIG. 5A, the wiring board 10 is manufactured, using conventional techniques. Then, the underfill resin 71 is formed on the wiring board 10 to cover the wiring layer 15 exposed in the openings 16x. The underfill resin 71 may be formed by, for example, laminating the first surface of the wiring board 10 with a B-stage (semi-cured) resin film (of epoxy resin or the like). Alternatively, resin (such as epoxy resin) in the form of liquid or paste may be applied on the first surface of the wiring board 10 by printing and thereafter be prebaked into a B-stage state.

Furthermore, the semiconductor chip 30, including the through electrodes 34 and the pads 35 formed on the upper end faces of the through electrodes 34, is prepared. The pads 35 are formed into a convex shape as depicted in FIG. 3A by electroless plating. The bonding parts 62 are formed at the lower ends of the connection terminals 41 of the semiconductor chip 30. The bonding parts 62 may be formed by, for example, applying cream solder (such as Sn—Ag solder) to the lower ends of the connection terminals 41 and performing reflow soldering.

Next, the semiconductor chip 30 and the wiring board 10 are aligned so that the connection terminals 41, on which the bonding parts 62 are formed, are positioned above the wiring layer 15 exposed in the openings 16x, and the semiconductor chip 30 is thereafter pressed toward the wiring board 10. As a result, the connection terminals 41, on which the bonding parts 62 are formed, pierce through the underfill resin 71 in a B-stage state, so that the bonding parts 62 contact the wiring layer 15 exposed in the opening 16x.

Next, in the process depicted in FIG. 5B, the semiconductor chip 30 is mounted on the wiring board 10 by flip chip bonding. Specifically, heating is performed while pressing the semiconductor chip 30 toward the wiring board 10. As a result, the bonding parts 62 melt and thereafter solidify, so that the connection terminals 41 and the wiring layer 15 exposed in the opening 16x are bonded through the bonding parts 62. At the same time, the underfill resin 71 is thermally cured. The underfill resin 71 fills in the space between the wiring board 10 and the semiconductor chip 30 to cover the connection terminals 41 and the boding parts 62.

Next, in the process depicted in FIG. 5C, the underfill resin 72 is formed on the semiconductor chip 30 to cover the pads 35. The underfill resin 72 may be formed by, for example, laminating the first surface of the semiconductor chip 30 with a B-stage (semi-cured) resin film (of epoxy resin or the like). Alternatively, resin (such as epoxy resin) in the form of liquid or paste may be applied on the first surface of the semiconductor chip 30 by printing and thereafter be prebaked into a B-stage state.

Next, in the process depicted in FIG. 5D, the semiconductor chip 50, including the connection terminals 54, is prepared. Then, the bonding parts 63 are formed at the lower ends of the connection terminals 54 of the semiconductor chip 50. The bonding parts 63 may be formed by, for example, applying cream solder (such as Sn—Ag solder) to the lower ends of the connection terminals 54 and performing reflow soldering.

Next, in the process depicted in FIG. 5E, the semiconductor chip 50 is mounted on the semiconductor chip 30 by flip chip bonding. Specifically, the semiconductor chip 30 and the semiconductor chip 50 are disposed so that the first surface of the semiconductor chip 30, at which the pads 35 are formed, and the second surface of the semiconductor chip 50, at which the connection terminals 54 are formed, face each other. At this point, the upper end faces 34a of the through electrodes 34, facing toward the semiconductor chip 50, and the second surfaces 54a of the connection terminals 54, facing toward the semiconductor chip 30, do not overlap each other in a plan view. Thereafter, the semiconductor chip 50 is pressed toward the semiconductor chip 30. As a result, the connection terminals 54, on which the bonding parts 63 are formed, pierce through the underfill resin 72 in a B-stage state, so that the bonding parts 63 contact the pads 35 at positions offset from the pads 35.

Next, heating is performed while pressing the semiconductor chip 50 toward the semiconductor chip 30. As a result, the bonding parts 63 melt and thereafter solidify, so that the pads 35 and the connection terminals 54 are bonded through the bonding parts 63 in the positional relationship depicted in FIGS. 3A and 3B, to be electrically connected. At this point, the topmost surfaces of the pads 35 are defined by the outer plating layers 352 formed of, for example, a Au layer having good wettability with solder, of which the bonding parts 63 are formed. As a result, even when the through electrodes 34 and the connection terminals 54 are positioned offset from each other, wet solder spreads over the entire top surfaces of the outer plating layers 352, so that the amount of the boding parts 63 at the connections of the pads 35 and the connection terminals 54 becomes sufficiently large.

Furthermore, the underfill resin 72 is thermally cured. The underfill resin 72 fills in the space between the semiconductor chip 30 and the semiconductor chip 50 to cover the connection terminals 54 and the bonding parts 63. The underfill resin 72 extends onto the periphery of the underfill resin 71 between the wiring board 10 and the semiconductor chip 50.

After the process depicted in FIG. 5E, the encapsulation resin 79 is formed to encapsulate the semiconductor chips 30 and 50 successively stacked on the wiring board 10. Furthermore, the solder bumps 61 are formed on the lower surface of the wiring layer 25 exposed in the openings 26x, as required. Thereby, the semiconductor device 1 depicted in FIGS. 1 and 2 is completed.

In the case of using a thermosetting mold resin as the encapsulation resin 79, the structure depicted in FIG. 5E is accommodated in a mold, and a mold resin to which a predetermined pressure is applied is introduced into the mold. Thereafter, the mold resin is heated to be cured to form the encapsulation resin 79.

Thus, according to the first embodiment, the semiconductor chip 30 and the semiconductor chip 50 are disposed so that the upper end faces 34a of the through electrodes 34, facing toward the semiconductor chip 50, and the second surfaces 54a of the connection terminals 54, facing toward the semiconductor chip 30, do not overlap each other in a plan view. As a result, it is possible to prevent stress concentration on the through electrodes 34.

Consequently, it is possible to prevent a problem, such as generation of cracks in the through electrodes 34, from being caused when an upper semiconductor chip is mounted or when the ambient temperature repeatedly changes after the mounting of the upper semiconductor chip. Accordingly, it is possible to improve the reliability of the connection of vertically adjacent semiconductor chips. This connection structure (depicted in FIGS. 3A and 3B) is particularly effective when the through electrodes 34 are small in diameter.

Furthermore, the convex pads 35 are formed on the through electrodes 34 by electroless plating, and the topmost surfaces of the pads 35 are defined by the outer plating layers 352 formed of, for example, a Au layer having good wettability with solder, of which the bonding parts 63 are formed. As a result, even when the through electrodes 34 and the connection terminals 54 are positioned offset from each other, wet solder spreads over the entire top surfaces of the outer plating layers 352, so that the amount of the boding parts 63 at the connections of the pads 35 and the connection terminals 54 becomes sufficiently large. Therefore, the through electrodes 34 and the connection terminals 54 are connected with high reliability through the pads 35 and the boding parts 63.

### [b] Second Embodiment

According to a second embodiment, semiconductor chips are stacked in more layers than in the first embodiment. In the second embodiment, a description of the same elements or configurations as those of the embodiment described above may be omitted.

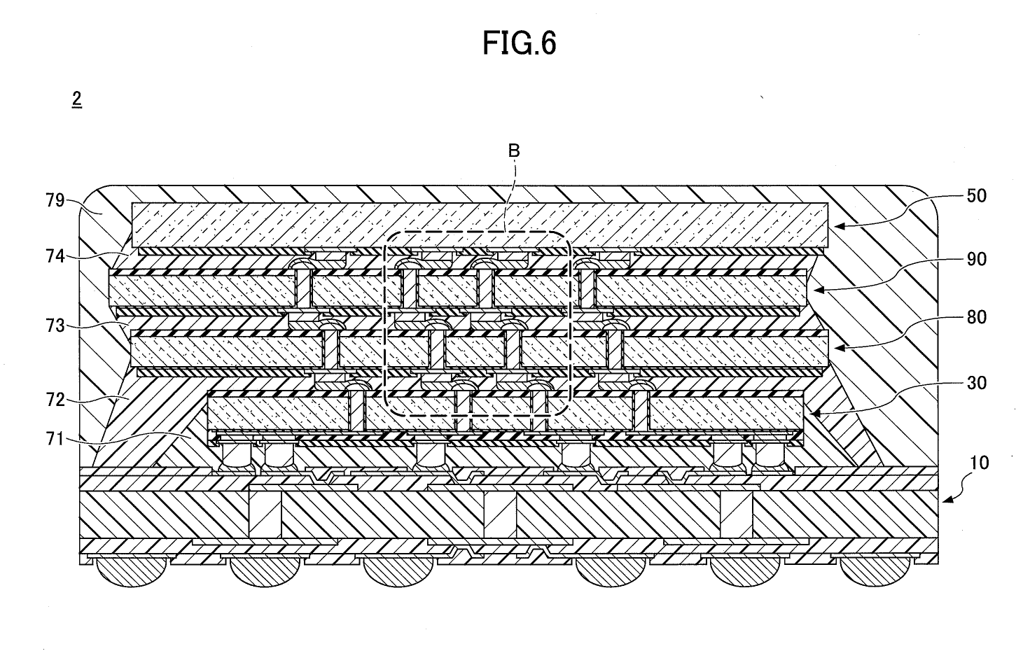

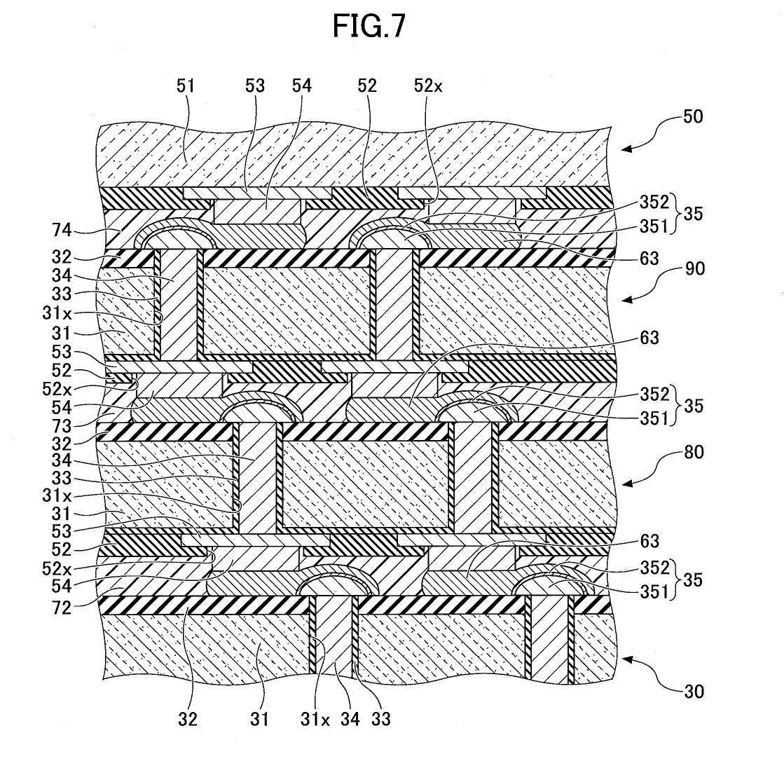

FIG. 6 is a cross-sectional view of a semiconductor device according to the second embodiment. FIG. 7 is an enlarged view of part of FIG. 6 indicated by B. In FIG. 6, for the convenience of depiction, the details are not referred to using reference numerals.

Referring to FIG. 6, a semiconductor device 2 includes the wiring board 10, the semiconductor chip 30, the semiconductor chip 50, a semiconductor chip 80, and a semiconductor chip 90. According to the semiconductor device 2, the semiconductor chip 30, the semiconductor chip 80, the semiconductor chip 90, and the semiconductor chip 50 are successively stacked on the wiring board 10. The semiconductor chip 80 and the semiconductor chip 90, which are referred to using different reference numerals for the convenience of description, have the same structure.

The space between the wiring board 10 and the semiconductor chip 30 is filled with the underfill resin 71. The space between the semiconductor chip 30 and the semiconductor chip 80 is filled with the underfill resin 72. Furthermore, the space between the semiconductor chip 80 and the semiconductor chip 90 is filled with an underfill resin 73, and the space between the semiconductor chip 90 and the semiconductor chip 50 is filled with an underfill resin 74.

As depicted in FIGS. 6 and 7, each of the semiconductor chips 80 and 90 is formed by providing a semiconductor chip having the same structure as the semiconductor chip 50 with the through holes 31x, the insulating layer 32, the insulating film 33, the through electrodes 34, and the pads 35, formed in the same manner as in the semiconductor chip 30. In the semiconductor chips 80 and 90, the through electrodes 34 are formed on the upper surfaces of the pads 53.

According to the semiconductor device 2, vertically adjacent semiconductor chips are disposed so that an end face of the through electrode 34 formed in one of the adjacent semiconductor chips, facing toward the other of the adjacent semiconductor chips, and a surface of the connection terminal 54 formed in the other of the adjacent semiconductor chips, facing toward the one of the adjacent semiconductor chips, do not overlap each other in a plan view. Like in the first embodiment, the pad 35 is formed on the through electrode 34, and the entire top surface of the pad 35 is defined by the outer plating layer 352 formed of, for example, a Au layer having good wettability with solder. Therefore, even when the through electrode 34 and the connection terminal 54 are positioned offset from each other, the through electrode 34 and the connection terminal 54 are connected with high reliability. The number of semiconductor chips to be stacked may be determined as desired.

Thus, in the case of stacking three or more semiconductor chips as well, by placing the connection terminal 54 at a position offset from the through electrode 34 in vertically adjacent semiconductor chips, it is possible to prevent stress concentration on the through electrode 34 the same as in the first embodiment. As a result, the same effects as in the first embodiment are produced.

Furthermore, the convex pad 35 is formed on the through electrode 34 by electroless plating, and the entire top surface of the pad 35 is defined by the outer plating layer 352 formed of, for example, a Au layer having good wettability with solder. Therefore, like in the first embodiment, the wet bonding part 63 spreads over the entire surface of the outer plating layer 352. As a result, even when the through electrode 34 and the connection terminal 54 are positioned offset from each other, the through electrode 34 and the connection terminal 54 are connected with high reliability because the amount of the boding part 63 at the connection of the pad 35 and the connection terminal 54 is sufficiently large.

### Variation of First Embodiment

According to a variation of the first embodiment, the through electrodes 34 and the connection terminals 54 are not offset in a uniform direction. In the variation, a description of the same elements or configurations as those of the embodiments described above may be omitted.

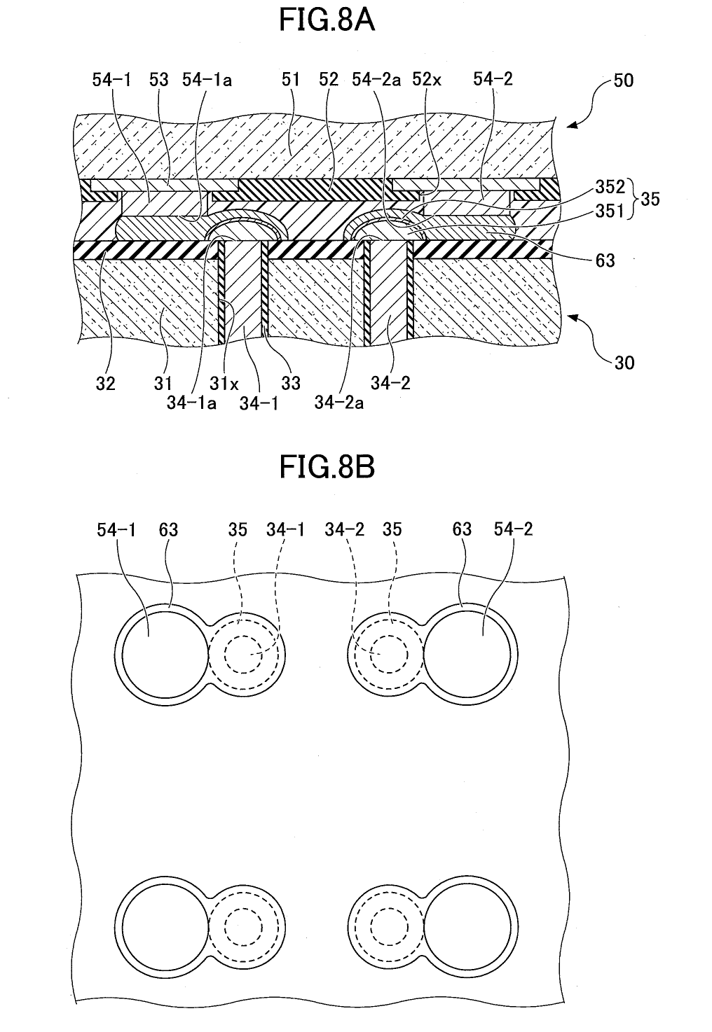

FIGS. 8A and 8B are enlarged views of part of a semiconductor device, depicting a structure of connections of semiconductor chips. FIG. 8A is a cross-sectional view, and FIG. 8B is a see-through plan view. Referring to FIGS. 8A and 8B, the semiconductor chip 30 includes adjacent through electrodes 34-1 and 34-2. Furthermore, the semiconductor chip 50 includes adjacent connection terminals 54-1 and 54-2.

An upper end face 34-1a of the through electrode 34-1, facing toward the semiconductor chip 50, and a second surface 54-1a of the connection terminal 54-1, facing toward the semiconductor chip 30, are positioned offset from each other in a predetermined direction (a direction to position the connection terminal 54-1 to the left of the through electrode 34-1) so as not to overlap each other in a plan view.

On the other hand, an upper end face 34-2a of the through electrode 34-2, facing toward the semiconductor chip 50, and a second surface 54-2a of the connection terminal 54-2, facing toward the semiconductor chip 30, are positioned offset from each other in a direction opposite to the predetermined direction (a direction to position the connection terminal 54-2 to the right of the through electrode 34-2) so as not to overlap each other in a plan view.

Thus, all through electrodes and connection terminals do not have to be offset in the same direction, the direction in which through electrodes and connection terminals are offset may be determined with respect to each pair of a through electrode and a connection terminal. The illustrated configuration is effective, for example, when the pitch of the through electrodes 34-1 and 34-2 depicted in FIGS. 8A and 8B is particularly narrower than the pitch of other through electrodes. The illustrated configuration, which is described as a variation of the first embodiment, may also be applied to the second embodiment.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

For example, the wiring board 10 does not necessarily have to be a resin substrate, and may be, for example, a ceramic substrate. Furthermore, the wiring board 10 is not always necessary, and the semiconductor device may have a structure where only semiconductor chips are stacked.

Furthermore, in the above description, by way of example, the process of mounting the semiconductor chip 30 after application of the underfill resin 71 onto the wiring board 10 is illustrated. Alternatively, the space between the wiring board 10 and the semiconductor chip 30 may be filled with the underfill resin 71 after mounting the semiconductor chip 30 on the wiring board 10. The same is the case with the underfill resins 72, 73 and 74.

Various aspects of the subject-matter described herein may be set out non-exhaustively in the following numbered clause:

1. A method of manufacturing a semiconductor device, including:

preparing a first semiconductor chip including a through electrode and a pad formed on an end face of the through electrode by electroless plating;

preparing a second semiconductor chip including a connection terminal at a surface thereof; and

stacking the first semiconductor chip and the second semiconductor chip so that the surface of the second semiconductor chip faces toward a surface of the first semiconductor chip at which the pad is positioned, and electrically connecting the pad and the connection terminal by a bonding part,

wherein in electrically connecting the pad and the connection terminal, the first semiconductor chip and the second semiconductor chip are disposed so that the end face of the through electrode, facing toward the second semiconductor chip, and a surface of the connection terminal, facing toward the first semiconductor chip, do not overlap each other when viewed in a direction in which the second semiconductor chip is stacked on the first semiconductor chip.

What is claimed is:

1. A semiconductor device, comprising:
a first semiconductor chip;
a second semiconductor chip stacked on the first semiconductor chip in a stacking direction,
wherein the first semiconductor chip includes
a through electrode; and
a pad on an end face of the through electrode, facing toward the second semiconductor chip,
wherein the second semiconductor chip includes a connection terminal at a surface thereof facing toward the first semiconductor chip,
wherein the end face of the through electrode and a surface of the connection terminal, facing toward the first semiconductor chip, do not overlap each other when viewed in the stacking direction, and
wherein the pad and the connection terminal are electrically connected by a bonding part.

2. The semiconductor device as claimed in claim 1, wherein the pad has a convex dome shape whose height decreases in a direction from a center to a periphery of the dome shape.

3. The semiconductor device as claimed in claim 1, wherein the pad extends beyond a perimeter of the end face of the through electrode.

4. The semiconductor device as claimed in claim 1, wherein the bonding part is formed on the surface of the connection terminal to cover a surface of the pad.

5. The semiconductor device as claimed in claim 1, wherein
the first semiconductor chip further includes another through electrode adjacent to the through electrode,
the second semiconductor chip further includes another connection terminal adjacent to the connection terminal,
the end face of the through electrode and the surface of the connection terminal are offset in a first direction when viewed in the stacking direction, and
an end face of said another through electrode, facing toward the second semiconductor chip, and a surface of said another connection terminal, facing toward the first semiconductor chip, are offset in a second direction different from the first direction so as not to overlap each other when viewed in the stacking direction.

6. The semiconductor device as claimed in claim 1, wherein the pad includes
an inner plating layer in contact with the end face of the through electrode; and
an outer plating layer covering an entire exterior surface of the inner plating layer.

7. The semiconductor device as claimed in claim 1, wherein the outer plating layer is a gold layer.

8. The semiconductor device as claimed in claim 1, further comprising:
at least one third semiconductor chip on which the first semiconductor chip is stacked in the stacking direction,
wherein the first semiconductor chip further includes a connection terminal at a surface thereof facing toward the at least one third semiconductor chip,
wherein the at least one third semiconductor chip includes
a through electrode; and
a pad on an end face of the through electrode, facing toward the first semiconductor chip,
wherein the end face of the through electrode of the at least one third semiconductor chip and a surface of the connection terminal of the first semiconductor chip, facing toward the at least one third semiconductor chip, do not overlap each other when viewed in the stacking direction, and
wherein the pad of the at least one third semiconductor chip and the connection terminal of the first semiconductor chip are electrically connected by another bonding part.

9. A semiconductor device, comprising:
a plurality of semiconductor chips successively stacked in a stacking direction,
wherein, in each of one or more pairs of adjacent semiconductor chips in the plurality of semiconductor chips,
one of the adjacent semiconductor chips on which the other of the adjacent semiconductor chips is stacked, includes
a through electrode; and
a pad on an end face of the through electrode, facing toward the other of the adjacent semiconductor chips,
the other of the adjacent semiconductor chips includes a connection terminal at a surface thereof facing toward the one of the adjacent semiconductor chips,
the end face of the through electrode and a surface of the connection terminal, facing toward the one of the adjacent semiconductor chips, do not overlap each other when viewed in the stacking direction, and
the pad and the connection terminal are electrically connected by a bonding part.
